(19) United States
(12) Patent Application Publication
(10) Pub. No.: US 2013/0320976 A1
(43) Pub. Date: Dec. 5, 2013

(54) METHOD AND MAGNETIC RESONANCE SYSTEM TO MEASURE A SODIUM CONTENT IN TISSUE BY MEANS OF A MAGNETIC RESONANCE TECHNIQUE

(71) Applicants: Robert Krieg, Nuernberg (DE); Sebastian Schmidt, Weisendorf (DE); Michael Uder, Uttenreuth (DE)

(72) Inventors: Robert Krieg, Nuernberg (DE); Sebastian Schmidt, Weisendorf (DE); Michael Uder, Uttenreuth (DE)

(21) Appl. No.: 13/906,635

(22) Filed: May 31, 2013

(30) Foreign Application Priority Data
May 31, 2012 (DE) 102012209173.4

(51) Int. Cl. G01R 33/32; G01R 33/44

(52) U.S. Cl. CPC G01R 33/32; G01R 33/44
USPC 324/309; 324/318

(57) ABSTRACT

In a magnetic resonance method and apparatus to measure a sodium content in tissue in a first slice, a determination of a blood volume in blood vessels in the first slice is made, and an MR acquisition sequence to acquire MR data of a sodium-23 magnetization from the first slice is implemented. A signal proportion of the MR data that originates from the sodium-23 magnetization in blood vessels is calculated based on the determined blood volume in tissue. This signal proportion is subtracted from a total signal of the MR data to obtain a corrected signal that is proportional to the sodium content in tissue. The sodium content in tissue is calculated from the corrected signal.

### BACKGROUND OF THE INVENTION

1. Field of the Invention

The present invention concerns methods to measure a sodium content in tissue of a first slice by magnetic resonance techniques, and magnetic resonance systems for implementing such a method.

2. Description of the Prior Art

Magnetic resonance (MR) is a technique or modality to acquire MR data from the inside of an examined person. Varied information can be acquired in such a manner. For example, by means of MR tomography it is possible to map structures with high resolution.

In general, in order to acquire MR data, magnetic moments of protons (i.e. hydrogen-1 nuclei) in an examination subject are aligned in a basic magnetic field. By radiating radio-frequency (RF) pulses, the nuclear spins can be deflected or excited out of the aligned state (i.e. the steady state) or another state. The chronological evolution of the excited magnetization is subsequently detected by one or more RF coils. Various types of information can be obtained from the parameters of the measured dynamic susceptibility, such as amplitude or half width.

The magnetization dynamic of the nuclear spins of protons is mapped conventionally. The gyromagnetic ratio γ for hydrogen-1 is 42.58 MHz/T. However, it is also possible to map the magnetization dynamic of other nuclei, for instance of sodium(Na)-23 nuclei. The different gyromagnetic ratio—in the cited case γ(sodium-23)=11.26 MHz/T—requires a corresponding adaptation of the RF or basic magnetic fields.

Applying a slice selection gradient upon radiation of the radio-frequency pulses causes nuclear spins in only a defined slice of the examination subject to be excited, because the slice selection gradient causes the resonance condition, which is determined by the gyromagnetic ratio due to the local magnetic field strength, to be satisfied only for the slice defined by that gradient. An additional spatial coding can take place by the application of at least one phase coding gradient, as well as a frequency coding gradient during the readout. It is thereby possible to obtain MR data selectively in a spatially selective manner from multiple slices of an examined person.

By means of sodium-23 MRT it is possible to determine a sodium content in a measurement volume. This can be desirable in medical applications. Conventional sodium-23 MRT is, however, not selectively sensitive to signal portions which are caused by moving magnetization within blood in a blood vessel, or by stationary magnetization in tissue. Medical applications can require such sensitivity.

### SUMMARY OF THE INVENTION

An object of the invention is to provide an improved method and an improved device that enable the sodium content in the tissue to be measured.

According to the invention, a method is provided to measure a sodium content in the tissue in a first slice by magnetic resonance, with saturation of a sodium-23 magnetization in a second slice by radiation of an RF saturation pulse, the second slice being located upstream of the first slice with regard to a flow direction of blood in a blood vessel proceeding through both slices. An MR acquisition sequence is used to obtain MR data of a sodium-23 magnetization from the first slice, with the arrangement of the first and second slices relative to one another being such that the sodium-23 magnetization in the blood vessel flows from the second slice into the first slice and has a signal portion that is reduced in the MR data. Furthermore, the method includes the computerized calculation of the sodium content in tissue from the MR data.

Selective excitation and detection of the magnetization from sodium(Na)-23 nuclei can take place by satisfaction of the resonance condition for these nuclei, for instance. The resonance condition can be provided by a static basic magnetic field, and optionally by gradient fields, and typically differs from the resonance condition of other nuclei (for instance of hydrogen-1 nuclei).

The RF saturation can then deflect the magnetization of the Na-23 nuclei out of the steady state, i.e. from the state parallel to the basic magnetic field (what is known as the longitudinal direction), for example. The longitudinal magnetization proportion is reduced, and a transverse component (orthogonal to the basic magnetic field, for example) can be generated.

The MR acquisition sequence can include the excitation, the manipulation of the phase position, for example; and the detection of a signal of the Na-23 magnetization. For example, the MR acquisition sequence can be designed to produce no further excitation in the first slice of the already saturated Na-23 magnetization, due to the preceding saturation of the Na-23 magnetization in the second slice. Therefore, this portion of the Na-23 magnetization that flows in the blood from the second slice into the first slice cannot contribute to the total signal, or contributes thereto only to a reduced extent, i.e. less strongly. This particularly applies in comparison to the case in which a preceding saturation of the Na-23 magnetization in the second slice has not occurred. The total signal of the MR data can accordingly include a reduced signal portion of the magnetization of Na-23 nuclei in the blood in contrast to Na-23 nuclei in tissue. The total signal of the MR data accordingly is proportional to the sodium content of the tissue.

In particular, an interval and/or a thickness of the first and second slices can be set (selected) based on at least one of the following variables: a flow rate of the blood in the blood vessel; a T1 spin-grid relaxation time of the sodium-23 magnetization; a signal strength.

The first and second slice may be parallel. The interval then designates the length of a vector situated orthogonally to a plane defined by the slices, which vector is limited by the two slices. The vector is parallel to the plane normal of the first and second slices. The interval can otherwise designate the interval of the slices along the blood vessel, for example.

If the parameters of interval and/or thickness of the first and second slices are established based on the flow rate of the blood and/or the T1 relaxation time (known as the longitudinal relaxation time or spin-grid relaxation time), it is thus ensured that the signal proportion of the Na magnetization in the blood is sufficiently strongly reduced.

For example, T1 for Na-23 can be approximately 55 ms, which is two orders of magnitude below T1 of hydrogen-1 in liquids. This can have the effect that the interval and/or thickness of the first and second slices is/are selected so small that a sufficiently saturated transverse component, and therefore a sufficiently reduced signal strength of Na-23 nuclei in blood relative to Na-23 nuclei in tissue, is present in the MR data.

In this regard, a high flow rate can have the effect that the saturated magnetization of Na-23 nuclei in the blood covers larger distances in the same time periods. This can mean that the same degree of relaxation of the previously saturated magnetization into the steady state—i.e. in the longitudinal direction—occurs along a larger traveled distance at higher flow rates in comparison to lower flow rates. Relatively high flow rates in the range of approximately 0.5-1.0 m/s occur in the aorta, for example. There the traveled distance can be particularly large, and therefore the signal proportion of the magnetization of Na-23 nuclei in the blood is particularly significantly reduced. It is possible that the aforementioned blood vessel is the aorta.

The blood vessel can have an orientation that is not orthogonal to the first and/or second slice. For example, the blood vessel can enclose an angle with the first and second slice that is other than 90°. The blood vessel then does not run parallel to the plane normal of the slices. Given the same flow rate, the time that Na-23 nuclei require in order to flow from the second slice into the first slice after the RF saturation pulse is longer, given the same flow rate. It can be possible to consider such a non-orthogonal orientation of blood vessels relative to at least one of the slices in the determination of the slice thicknesses or the interval.

At the same time, an increased thickness of the slices can ensure that a sufficiently high signal strength can be achieved by integration of the measured signal over a larger volume region. This in particular applies with regard to Na-23 MRT, in which a signal strength that is reduced in comparison to hydrogen-1 MRT can be present, for example.

It is possible for the thickness of the first slice and the thickness of the second slice to be the same. If the first slice and the second slice have the same thicknesses, this can have the effect that the signal proportion of Na-23 nuclei in the blood is reduced uniformly over the entire thickness of the first slice.

At least one of the following variables can be selected such that the reduced signal proportion is less than or equal to a predetermined fraction of a total signal of the MR data: a thickness of the first slice, a thickness of the second slice, and/or a distance of the first slice from the second slice. The predetermined fraction can be proportional to an accepted measurement inaccuracy of the Na content in the tissue. As already explained, an increased slice thickness can have the effect that the transversal magnetization component of the Na-23 nuclei in the blood is already reduced significantly via relaxation after the RF saturation pulse. If the thickness of the first and second slice is selected so that the transversal component does not fall below a defined value, so that the reduced signal proportion of sodium in the blood is therefore less than or equal to the predetermined fraction, under this requirement it can be possible to optimize the signal strength in that the slice thickness is chosen to be appropriately large.

For example, the separation of the first and second slices can be chosen to be as small as possible. The minimum achievable separation is typically limited by apparatus-specific limitations of a magnetic resonance (MR) system, for instance by the gradient field strength or the spatial sensitivity of the detection coils.

The RF saturation pulse can be slice-selective at the second slice. For example, only the magnetization of the second slice is then saturated, but the magnetization of the first slice is not. The MR acquisition sequence then deflects the magnetization in the stationary tissue of the first slice out of the steady state, i.e. generates transverse magnetization. The Na-23 nuclear spins that flow in the blood through the blood vessel from the second slice to the first slice can already be saturated by the RF saturation pulse at the point in time of the data acquisition, and can have a smaller signal proportion or no signal proportion in the MR data.

In contrast to this, it is also possible that the RF saturation pulse is not slice-selective, and that the MR acquisition sequence has a slice-selective second RF saturation pulse that re-inverts the magnetization in the first slice before implementing the remaining MR acquisition sequence. Before implementing the MR acquisition sequence, a large longitudinal component of the stationary magnetization in the tissue of the first slice can then initially be generated again. The MR acquisition sequence then acts on this longitudinal component. The second RF saturation pulse can be radiated after the first non-slice-selective RE saturation pulse but before the point in time at which the saturated, flowing magnetization in the second slice reaches the first slice. This ensures that the second RF saturation pulse does not act on the Na-23 nuclear spins which flow in the blood vessel from the second slice to the first slice.

The invention also encompasses a magnetic resonance that has a pulse sequence controller and a computer. The pulse sequence controller is configured to control a radio-frequency unit so that it radiates an RF saturation pulse such that sodium-23 magnetization in a second slice is saturated, with the second slice located upstream from a first slice in a blood vessel, with regard to the flow direction of blood. Furthermore, the pulse sequence controller is configured to implement an MR acquisition sequence to receive MR data of a sodium-23 magnetization from the first slice. The arrangement of the first slice and second slice relative to one another is established so that the sodium-23 magnetization flows in the blood vessel from the second slice into the first slice and has a reduced signal proportion in the MR data. Furthermore, the computer is configured to calculate a sodium content in the tissue from the MR data.

With such a magnetic resonance system advantages are achieved that correspond to those described with regard to the inventive method.

According to a further aspect, a method is provided to measure a sodium content in tissue in a first slice by means of a magnetic resonance technique. The method includes the determination of a blood volume in blood vessels in the first slice and the implementation of an MR acquisition sequence to acquire MR data of a sodium-23 magnetization from the first slice. The method furthermore includes the calculation of a signal proportion of the MR data which originates from the sodium-23 magnetization in the blood vessels, based on the determined blood volume in tissue, and the subtraction of this signal proportion from a total signal of the MR data to obtain a corrected signal which is proportional to the sodium content in tissue. Furthermore, the method includes the calculation of the sodium content in tissue from the corrected signal.

The subtraction of the signal proportion of the magnetization from Na-23 nuclei in the blood from the total signal, based on the determined blood volume in tissue, can enable the sodium content in tissue to be determined in examination regions that have particularly fine blood vessels with typically low flow rates. For example, the first slice can have many fine blood vessels therein.

At least one of the afore mentioned determination, calculation or subtraction can be implemented with spatial resolution. For example, if the blood vessel for individual voxels is determined with spatial resolution, the calculation of the signal proportion of the MR data which originates from the sodium-23 magnetization in blood vessels and the subtraction of this signal proportion in turn from the spatially resolved total signal can also take place. For example, if the blood volume varies for different positions within the first slice, it can thus be possible to achieve a particularly significant measurement of the sodium content in tissue via the spatially resolved subtraction. However, it is possible, for example, to calculate only the sodium content of the tissue with spatially averaging over the first slice. In this case, however, the averaging can only occur after the spatially resolved subtraction or at a different method step, for example.

A spatial resolution of the MR data can be lower than an average extent of blood vessels in the first slice. The spatial resolution of the MR data can be inversely proportional to the size of the voxel of the MR acquisition sequence, for example. For example, the voxel size increased when the spatially averaged blood volume remains constant as a function of the position within the first slice but the individual blood vessels that contribute to the averaged blood volume have a particularly small extent.

For instance, the blood volume in the tissue of the first slice can be determined by means of a second MR acquisition sequence to acquire second MR data of a hydrogen-1 magnetization. The hydrogen-1 MRT can have a higher signal (per magnetization, for example) in comparison to Na-23 MRT. In such cases, it can be desirable to determine the blood vessel by means of hydrogen-1 MRT. For example, it can then be possible to reduce the voxel size given the same signal, and therefore to achieve an increased spatial resolution. Methods such as “dynamic contrast medium enhanced” (DCE) MRT and “arterial spin labeling” (ASL) MRT are known for this purpose.

In general, it is possible for the second MR acquisition sequence to include an RF saturation pulse in a second slice which is arranged upstream of the first slice with regard to a flow of blood in a blood vessel. The blood volume within the first slice can then be determined, for example, by measurement of reference and measurement images with and without high signal proportion of magnetization in flowing blood. For example, upstream RF saturation pulses can be used to reduce the signal proportion of flowing hydrogen-1 magnetization in the blood. Such techniques are known as dark blood techniques.

The signal proportion of MR data that originates from the sodium-23 magnetization in the blood vessels can be calculated based on a multiplication of a concentration of sodium in blood with the defined blood volume in the first slice.

Such a multiplication can yield a value proportional to the signal portion of the Na-23 magnetization in blood vessels, for example. One possibility is to use a predetermined or, respectively, constant value of the concentration of sodium in the blood, for instance for adults (136-150 mmol/liter) or for children 130-145 (mmol/liter). It is also possible to determine the concentration of sodium in the blood. Known laboratory methods that need not be explained in detail herein can be used for this purpose.

According to a further aspect, a magnetic resonance system is provided that has a pulse sequence controller and a computer, wherein pulse sequence controller is configured to implement a second MR acquisition sequence to determine a blood volume in blood vessels of a first slice, and to implement an MR acquisition sequence to acquire MR data of a sodium-23 magnetization from the first slice. Furthermore, the computer is configured to calculate a signal proportion of the MR data which originates from the sodium-23 magnetization in blood vessels based on the determined blood volume in the tissue, and to subtract this signal proportion from a total signal of the MR data to obtain a corrected signal which is proportional to the sodium content in the tissue, and to calculate a sodium content in the tissue from the corrected signal.

With such a magnetic resonance system, advantages can be achieved that correspond to those described with regard to the corresponding method.

### BRIEF DESCRIPTION OF THE DRAWINGS

FIG. 1 schematically illustrates an MR system according to the invention.

FIG. 2 illustrates an RF saturation pulse and an MR acquisition sequence.

FIG. 3 illustrates the saturation of magnetization in blood that flows from a second slice into a first slice.

FIG. 4 illustrates the saturation of magnetization in blood that flows from a second slice into a first slice.

FIG. 5 illustrates the saturation of magnetization in blood that flows from a second slice into a first slice.

FIG. 6 illustrates an example of an arrangement of a first slice and second slice and a blood vessel.

FIG. 7 is a flowchart of a method to determine the sodium content in tissue in accordance with the invention.

FIG. 8 illustrates an example of an arrangement of fine blood vessels in a first slice.

FIG. 9 is a flowchart of a method to determine the sodium content in tissue.

### DESCRIPTION OF THE PREFERRED EMBODIMENTS

In the following, the invention is explained in more detail with reference to accompanying figures. The presented embodiments relate to techniques to determine a sodium content in tissue.

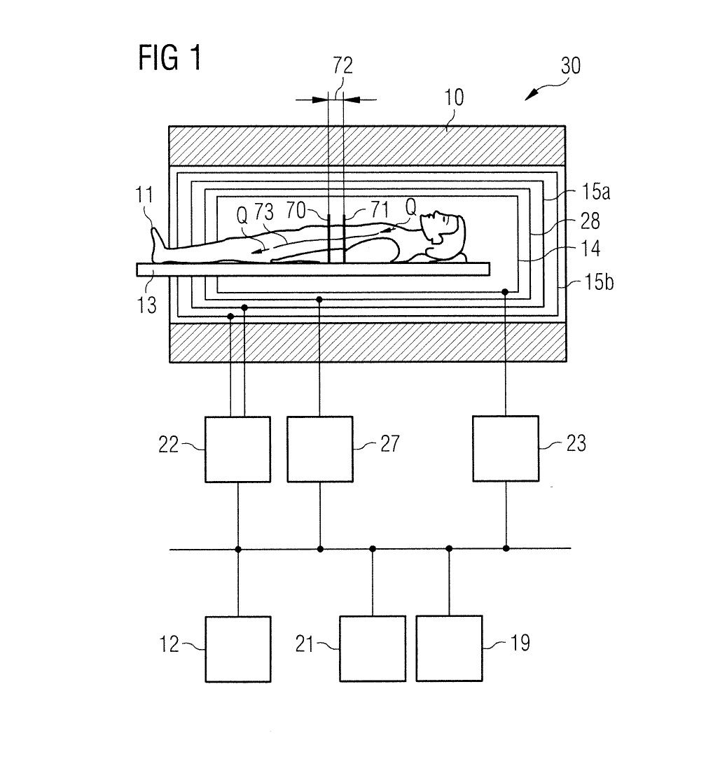

FIG. 1 schematically shows a magnetic resonance (MR) system 30 according to an embodiment of the present invention. The MR system has a magnet 10 to generate a polarization field or basic magnetic field. An examination subject—here an examined person 11—can be slid on a bed table 13 into a magnet 10. The MR system 30 furthermore has a gradient system 14 to generate magnetic field gradients that are used for imaging and spatial coding. For example, the magnetization in one of the slices 70, 71 can be acted upon selectively by means of the gradient system 14. A radio-frequency coil arrangement 28 that radiates a radio-frequency field into the examined person 11 in order to deflect the magnetization out of the steady state is provided to excite the polarization of the magnetization that results in the basic magnetic field. Therefore, the radio-frequency coil arrangement 28 is also designated as a transmission coil arrangement or excitation coil arrangement. Amplitude-modulated radio-frequency pulses are typically used to deflect the magnetization out of the steady state. A radio-frequency unit 27—that can, for instance, comprise a radio-frequency generator and an amplitude modulation unit—is used to generate such radio-frequency pulses. In particular, the radio-frequency unit 27 is designed to be able to provide various frequencies for the RF pulses. This enables resonances of both hydrogen-1 nuclei and sodium(Na)-23 nuclei to be excited and measured in a given basic magnetic field of the magnet 10. A gradient unit 23 is provided to control the gradient system 14.

The acquisition of magnetic resonance signals or, respectively, MR data can take place by means of the RF coils 15a, 15b that can inductively detect magnetization signals. The signals of the RF coils 15a, 15b can be detected by a computer 22. The different RF coils 15a, 15b can be adapted to the respective resonance frequencies of hydrogen-1 nuclei or Na-23 nuclei, for example. Such a measured Na-23 MR signal is typically proportional to a sum of the sodium content in the blood and tissue. This means that the MR signal can be proportional to a total number of Na-23 nuclear spins in the measurement volume.

For example, an MR acquisition sequence includes the excitation, the dephasing or rephasing, and the detection of a magnetization signal. The implementation of MR acquisition sequences in the magnetic resonance system 30 is centrally controlled by a pulse sequence controller 21. The pulse sequence controller 21 controls the radiation of RF pulses, the application of gradient fields and the acquisition of resulting MR data. Among other things, the gradient unit 23 can hereby be controlled by the pulse sequence controller 21 such that both the magnetization from a first slice 70 and the magnetization from a second slice 71 are selectively acted upon.

In FIG. 1, the slices 70, 71 each have a normal that is oriented parallel to the basic magnetic field and have a separation 72. In FIG. 1, the normal of each of the slices 70, 71 is situated in the plane of the drawing. Both slices 70, 71 contain portions of a blood vessel 73. In FIG. 1, the blood flows in blood vessel 73 from a second slice 71 in the direction of the first slice 70, i.e. in the distal direction. The direction of the blood flow is designated with Q.

The blood in blood vessel 73 has a defined flow rate. In this regard, the pulse sequence controller 19 is designed to implement the effect on the magnetizations of the first or, respectively, second slice 70, 71, matched to the separation 72 and the flow rate. For example, an RF saturation pulse can saturate the magnetization of the Na-23 nuclei in the second slice 71. The Na-23 nuclei flowing in the blood vessel 73 reach the first slice 70 after a defined time period that results from the flow rate and separation 72 or, respectively, from the orientation of blood vessel 73 with regard to slices 70, 71. If these Na-23 nuclei have reached the first slice 70, pulse sequence controller 21 is configured to implement an MR acquisition sequence to acquire MR data from the magnetization dynamic of Na-23 nuclei. The flowing Na-23 magnetization in the blood vessel 73 then has a reduced signal proportion of the total signal of the MR data. Pulse sequence controller 21 can also implement a comparable technique for the magnetization of hydrogen-1 nuclei. For example, techniques to determine the blood volume can be implemented via hydrogen-1 MRT methods such as ASL or DCE.

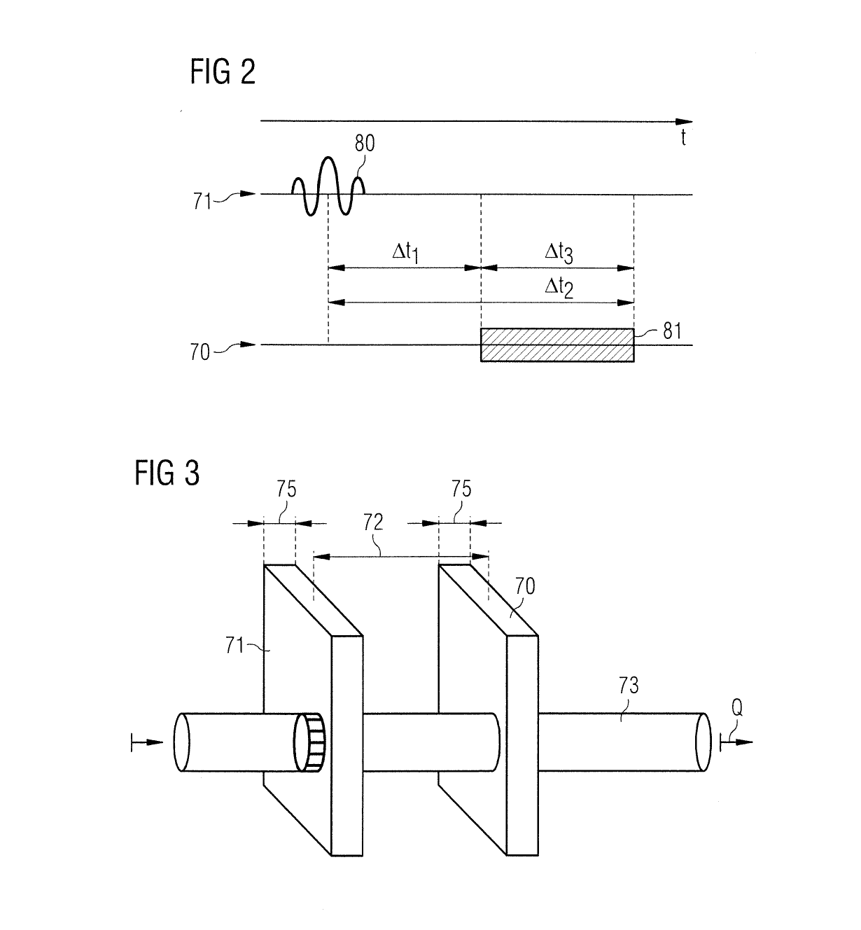

The computer 22 can then calculate the sodium content in tissue based on the MR data, for example. A processor can be used for this, for example. Such a technique is explained in detail in the following with reference to FIG. 2-9.

In this context, saturation of the magnetization means that a high transversal component of the magnetization is generated. This means that the magnetization is deflected out of its steady state, which typically proceeds parallel to the basic magnetic field, i.e. is oriented in the longitudinal direction.

While a slice-selective saturation pulse was used in the above exemplary embodiment, it is also possible to radiate a non-slice-selective saturation pulse, for example without applied gradient field. Non-slice-selective transversal magnetization is then generated, i.e. both in slice 71 and in slice 70. If MR data should subsequently be acquired from the first slice by means of an acquisition sequence, the magnetization of the first slice can thus be at least partially brought into the steady state again or be rephased before.

A reconstruction of image data from the raw MR data and a continuative processing of these takes place in image computer 19. An operator—for example a measurement sequence protocol—can be selected and imaging parameters can be input and modified via a computer 12. The general functionality of an MR system is known to those skilled in the art, such that a more detailed description of the general components is not necessary herein.

FIG. 2 illustrates in detail how the pulse sequence controller from FIG. 1 can act on the magnetization in the first slice 70 and in the second slice 71 according to an aspect of the invention by means of an MR acquisition sequence and by means of RF saturation pulses.

In the exemplary embodiment of FIG. 2, an RF saturation pulse 80 is initially radiated slice-selectively in the second slice 71. As was already explained above, it would also be possible to implement the RF saturation pulse 80 non-slice-selectively. The RF saturation pulse saturates the Na-23 magnetization.

The radiation of RF saturation pulse 80 is schematically illustrated in FIG. 2 by the amplitude modulation in the form of a sinc pulse. After a time period δt₁, an MR acquisition sequence 81 of time duration δt₃ to acquire MR data of the Na-23 magnetization is slice-selectively implemented for the first slice 70. This means that a time period δt₂ extends between the radiation of the RF saturation pulse 80 and the end of the MR acquisition sequence 81.

The time periods Δt₁, Δt₂, Δt₃ are selected such that the signal proportion of the MR data from acquisition sequence 81, which is caused by sodium-23 nuclear spins that flow in a blood vessel from the second slice 71 to the first slice 70, is reduced. This means that the time period δt₁ can be selected based on the flow rate, the orientation of the blood vessel relative to the first and second slice 70, 71, and also based on the spin-grid relaxation time T₁, for example.

If the time period δt₁ is significantly larger than the spin-grid relaxation time T₁, during the time period δt₃ the RF saturation pulse 80 no longer has an effect. The transversal magnetization that is generated by the RF saturation pulse is already relaxed in the longitudinal direction.

However, if the time period δt₁ is simultaneously chosen such that the magnetization of the second slice that is saturated by the RF saturation pulse 80 is arranged within the first slice 70 during the time period δt₃. This means that the blood and the Na-23 nuclei or hydrogen-1 nuclei included in said blood travels the distance between second slice 71 and first slice 70 within the time period Δt₁.

This is explained in detail with regard to FIG. 3. The first and second slice 70, 71 as well as a blood vessel 73 are shown there. The first and second slice 70, 71 have an identical thickness 75 and are arranged at a distance 72 from one another. The flow direction of the blood vessel 73 is indicated from left to right and with Q in FIG. 3. Referring to FIG. 2, a saturation of the magnetization in the second slice 71 takes place at a point in time. In particular, for example, the sodium-23 nuclear spins within the blood vessel 73 then have a high transversal component and a small longitudinal component. The quantity of these saturated Na-23 nuclear spins is indicated as a shaded volume in FIG. 3.

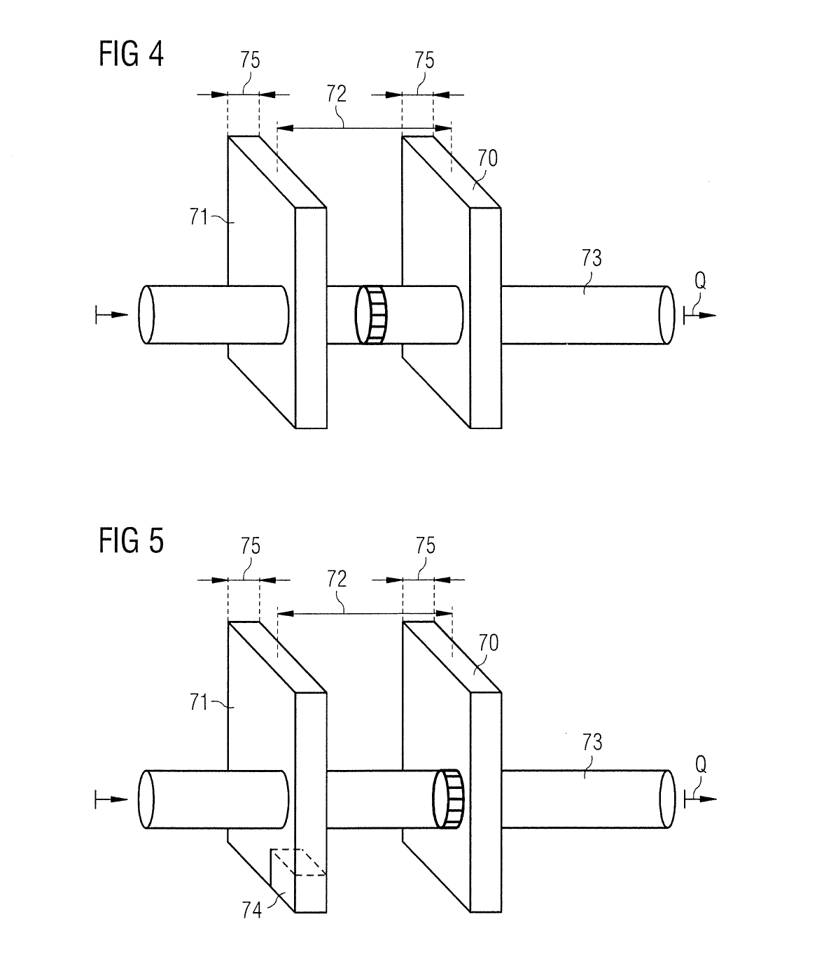

The corresponding situation is shown at later points in time in FIGS. 4 and 5. This means that the quantity of saturated sodium-23 nuclear spins moves with the flowing blood within blood vessel 73 in direction Q to the first slice 70.

With advancing time, the blood—and therefore the saturated Na-23 nuclear spins—moves closer to the first slice 70. At the same time, the transversal magnetization of the sodium-23 nuclear spins relaxes and the longitudinal magnetization component increases. The characteristic time period for this relaxation is the spin-grid relaxation time T1. This is not graphically indicated.

In FIG. 5, a situation is shown in which the blood volume of the saturated sodium-23 nuclear spins has reached the first slice 70. This is the point in time at which the acquisition sequence 81 from FIG. 2 is implemented. Since the sodium-23 nuclear spins or, respectively, the corresponding magnetization have a small longitudinal component or, respectively, are saturated within the blood vessel 73, the signal proportion of this magnetization is low in the total signal of the MR data that are obtained via the acquisition sequence implemented in the first slice. In particular, the signal proportion is reduced relative to the case without preceding saturation via an RF saturation pulse.

The markedly shorter spin-grid relaxation times T₁ of sodium-23 nuclei relative to hydrogen-1 nuclei in flowing blood should be noted. For example, T₁ of sodium is approximately 55 milliseconds, which can be shorter by a factor of 100 relative to T1 of hydrogen-1 nuclei. This means that the distance that the blood can travel during the T₁ spin-grid relaxation time is much shorter for sodium-23 nuclei in comparison to hydrogen-1 nuclei. In this regard, it can be desirable if the separation 72 between the first and the second slice 70, 71 is small. Namely, it can then be ensured that only a small proportion of the transversal Na-23 magnetization is relaxed in the longitudinal direction up to and during implementation of the MR acquisition sequence in the first slice 70.

Furthermore, it should be noted that the implementation of the acquisition sequence to obtain MR data of the Na-23 magnetization itself requires a certain amount of time, for example the time period designated time Δt₃ in FIG. 2. For example, it can be desirable to ensure that saturated Na-23 magnetization is present in the first slice 70 during the entire duration of the acquisition sequence. For example, this can be achieved via a matching of the slice thicknesses to the flow rate and the time required to implement the acquisition sequence.

With regard to FIG. 3 through 5, it is also to be noted that it is also possible that the RF saturation pulse is not slice-selective. In particular in the first slice 70, a transverse magnetization component is then also generated, meaning that the magnetization in the first slice is already saturated at the point in time of the RF saturation pulse 80 in FIG. 2. Nevertheless, in order to be able to acquire MR data from the first slice 70 by means of the MR acquisition sequence 81 (as it has been discussed in the preceding), an additional, second RF saturation pulse can for example act slice-selectively on the magnetization of the first slice 70. This RE saturation pulse can be implemented at the beginning within the scope of the MR acquisition sequence 81, for example, in order to relax the transversal component of the magnetization of the sodium-23 nuclear spins (which are stationary in the tissue of the first slice (70), for example) into the steady state in such a manner. The MR acquisition sequence can subsequently be implemented as already described above.

Furthermore, a voxel 74 is shown in FIG. 5. A voxel 74 corresponds to a limited spatial volume within which MR data are acquired in an integrated manner, i.e. without additional spatial resolution. In other words: the spatial resolution of an MR acquisition sequence is inversely proportional to the spatial extent of a voxel 74. It can be desirable that the spatial extent of the voxel 74 is approximately on the order of the spatial extent of the blood vessel 73. It can then be possible to determine the sodium content in the tissue particularly precisely or to implement a determination of the sodium content with spatial resolution.

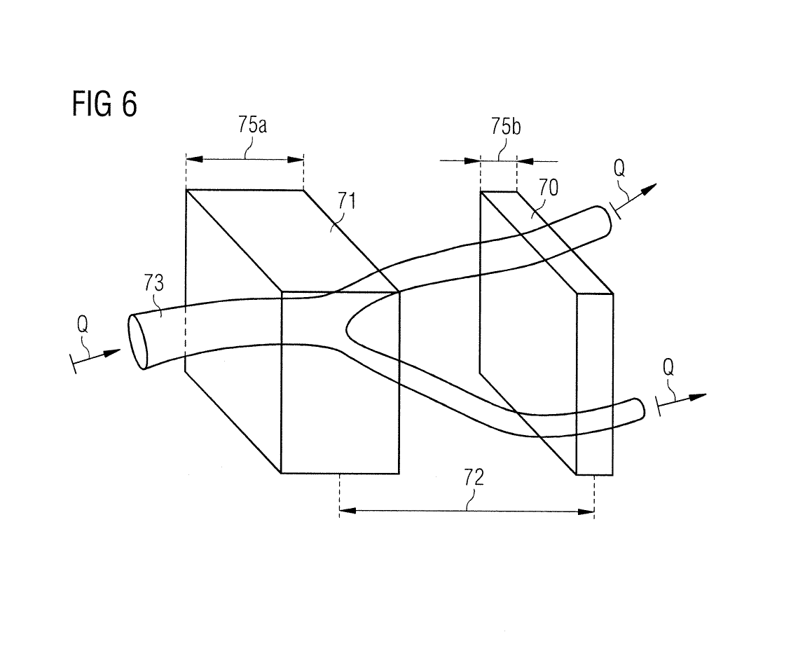

An arrangement of first and second slice 70, 71 that corresponds to FIG. 3 through 5 is shown with regard to FIG. 6. However, the blood vessel 73 in FIG. 6 has a more complicated arrangement relative to the slices 70, 71. In particular, the blood vessel 73 divides into two blood vessels between the second slice 71 and the first slice 70. Moreover, the blood vessel 73 encloses an angle with the slice normals of the slices 70, 71. This can mean that the time period Δt₁ that is discussed with regard to FIG. 2—i.e. the time period which the blood requires in order to flow from the second slice 71 to the first slice 70—increases in comparison to an arrangement of the blood vessels as it is shown in FIG. 3 through 5. The distance traveled by blood is namely greater than the geometric interval between the first and second slice 70, 71.

Furthermore, the flow rate of the blood can change as a function of the position along the blood vessel 73. This can be the case due to a change of the cross section of the blood vessel. In order to correctly dimension the time period Δt₁ of FIG. 2, it can be necessary to know the flow rate with spatial resolution. However, it is also possible to know only the total time period Δt₁ without knowledge of the underlying curve of the flow rate in order to implement the acquisition sequence to acquire Na-23 MR data at the correct point in time.

Furthermore, the second slice 71 in FIG. 6 has a slice thickness 75a which is greater than the slice thickness 75b of the first slice 70. For example, it can therefore be possible to ensure that the magnetization flowing with the blood in the blood vessel 73 is saturated by the RF saturation pulse during the entire duration of the acquisition sequence 81 (as it is designated with Δt₃ in FIG. 2). For example, this can be desirable if the flow rate of the blood between the slices 70, 71 not only assumes an exact value but rather has a distribution of flow rates between a maximum value and a minimum value, for example due to the presence of multiple blood vessels or bifurcations etc.

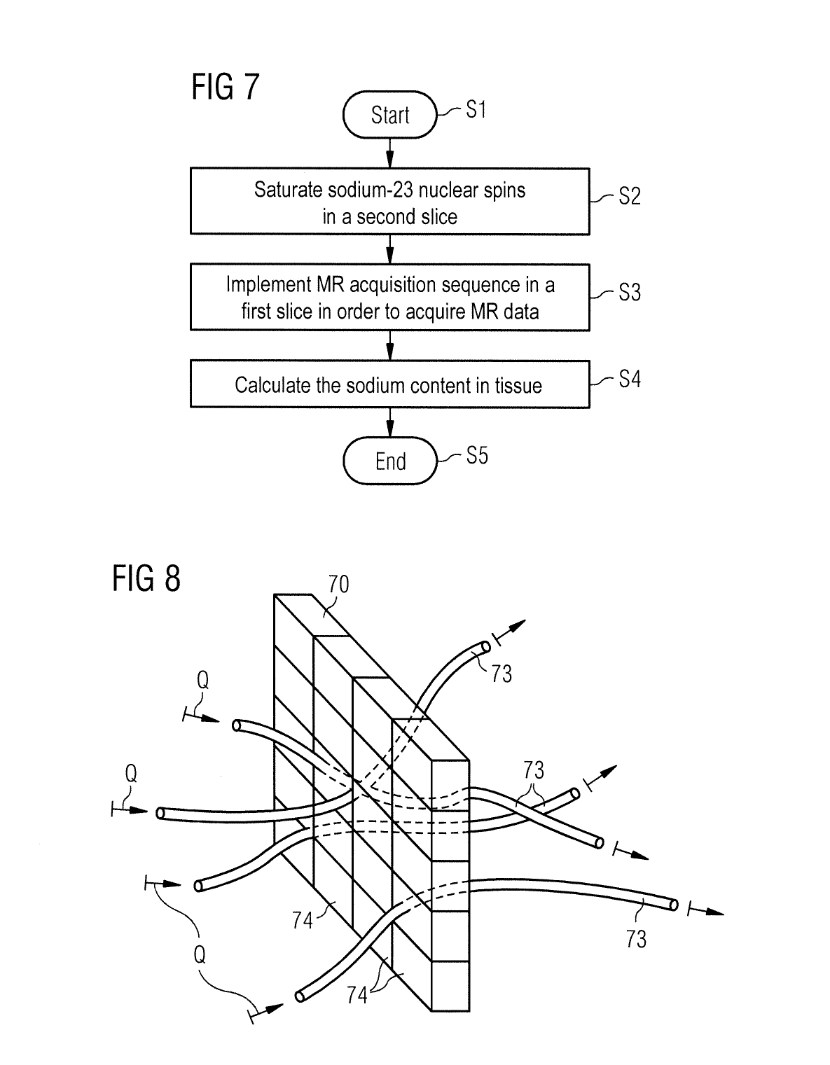

FIG. 7 shows a flow diagram of a method to determine the sodium content in tissue. The method begins with Step S1.

The sodium-23 magnetization in a second slice is saturated in Step S2. The saturation takes place via an RF saturation pulse, for example. This saturation pulse can act slice-selectively only on the magnetization within the second slice, for example. However, it is also possible that the RF saturation pulse does not act slice-selectively on the magnetization within a defined examination subject.

In Step S3, an MR acquisition sequence is implemented in a first slice in order to obtain MR data. In particular, the MR acquisition sequence is implemented on sodium-23 nuclear spins. The beginning of Step S3 is implemented with a delay of a time period Δt₁ relative to the implementation of Step S2. The time period δt₁ is selected such that the sodium-23 magnetization that is saturated in Step S2 flows in a blood vessel from the second slice into the first slice and is located within said first slice during the acquisition of the MR data. The sodium-23 magnetization in the blood vessel then has a reduced signal proportion in the MR data in comparison to the case without implementation of Step S2. The sodium-23 magnetization in the blood vessel also has a reduced signal proportion relative to the stationary sodium-23 magnetization in the first slice (for example in the tissue). The signal of the MR data from Step S3 can thus be proportional to the sodium content in the tissue.

Therefore, the sodium content in tissue can be calculated, for example in a computer of a magnetic resonance system that has a processor. The method ends in Step S5.

In FIG. 8, a situation is shown in which multiple blood vessels 73 are comprised by the first slice 70. In particular, the blood vessels shown in FIG. 8 are very fine blood vessels which have a small extent. For example, the extent of the blood vessels 73 of FIG. 8 is smaller than the extent of the blood vessel 73 in FIG. 3-6. Such a small extent typically entails low flow rates of the blood located in the blood vessels 73. In FIG. 8, the extent of a voxel 74—i.e. of the spatial region for which a spatial coding is implemented within an MR acquisition sequence—is greater than the average extent of the blood vessels 73.

If a method according to the preceding FIG. 7 is applied in a situation as it is shown in FIG. 8, it is to be noted that the time period between Steps S2 and S3—i.e. the time period between saturation of the magnetization in the second slice and implementation of the MR acquisition sequence in the first slice—is comparably long since the flow rate of the blood through the fine blood vessels 73 is significantly lower than the flow rate through large blood vessels, for example.

For example, the flow rate in the blood in a large blood vessel (the aorta, for example) can be in a range from 0.5 to 1.5 m/sec. However, the flow rate of blood in finer blood vessels 73 as they are shown in FIG. 8 can assume significantly lower values, for example less than 0.1 m/sec or lower. Since the minimum distance between the first and second slice 70, 71 in FIG. 3 through 6 is typically limited by hardware limitations of the magnetic resonance system (for example minimum voxel size), the time period Δt₁ between the RF saturation pulse and the MR acquisition sequence may assume values on the order of or larger than the spin-grid relaxation time T₁ of sodium-23 nuclear spins. This spin-grid relaxation time T₁ for sodium-23 is on the order of approximately 55 ms.

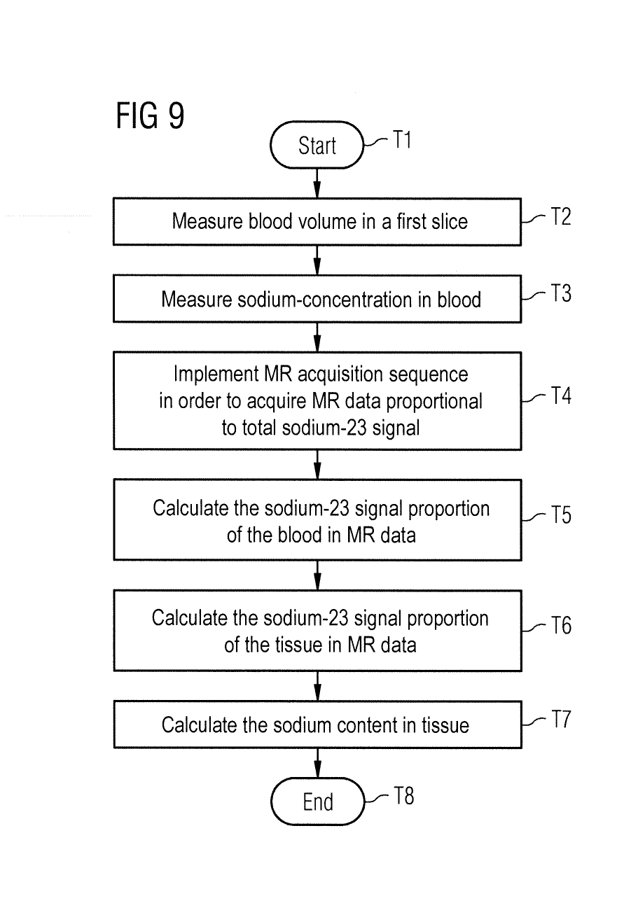

In such a situation as it is shown in FIG. 8, the sodium content in tissue can be determined by means of a method as it is schematically illustrated by the flow chart presented in FIG. 9, for example. The method begins in Step T1. The blood volume in a first slice is initially measured in Step T2. The measurement of the blood vessel in Step T2 can be implemented by means of MR measurements of hydrogen-1 nuclei, for example. Methods for this (such as ASL or DCE) are known to the man skilled in the art. Via MR of hydrogen-1 nuclei, the effect can be produced that such measurements have an increased signal in comparison to sodium-23 MR. For example, the size of a voxel can then be chosen to be smaller given the same signal. A more precise or faster determination of the blood vessel can thereby be possible.

Step T3 is an optional step. The sodium concentration in blood is measured in Step T3. This can occur by means of laboratory methods known to the man skilled in the art. In particular, the sodium concentration—i.e. concentration of various isotopes—in the blood can be proportional or equal to the sodium-23 concentration in the blood. If Step T3 is not implemented, a value for the sodium concentration in the blood that is known from the literature can be chosen. The actual value typically does not difference significantly or differs only slightly from the literature value.

Step T4 is subsequently implemented. In Step T4, an MR acquisition sequence is implemented in order to obtain MR data which are proportional to a total sodium-23 signal. The total sodium-23 signal is composed of signal portions of Na-23 magnetization which flows within blood vessels and Na-23 magnetization which is stationary within tissue. The goal of steps T5 through T7 is therefore to determine the signal proportion of the total sodium-23 signal which is caused by the stationary sodium-23 magnetization in the tissue. It thus results that: total Na-23 signal=Na-23 signal from tissue+Na-23 signal from blood.

For this, in Step T5 the signal proportion of the total signal which originates from Na-23 magnetization flowing in a blood vessel is initially calculated. For example, this occurs via multiplication of the Na-23 concentration in the blood (as it was measured in Step T3, for example) with the blood vessel in the first slice that was measured in Step T2. The multiplication of these two values yields a value which is proportional to the signal proportion of Na-23 magnetization in the blood that is to be determined in Step T5. It results as:

Total Na-23 signal=Na-23 signal from tissue+Na-23 concentration in the blood×blood volume.

Based on this, the signal portion of the total Na-23 signal that originates from the static magnetization in the tissue (for example in the tissue [sic]) can be calculated (Step T6). For example, the calculation takes place via subtraction of the Na-23 signal from magnetization in the blood from the total signal. If this proportion is determined in Step T6, in Step T7 the sodium content in the tissue can be calculated from this. Namely, the signal proportion of the static Na-23 magnetization is typically proportional to the sodium content in the tissue.

The method ends at Step T8.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method to measure a sodium content in tissue of a subject, comprising:
operating a magnetic resonance data acquisition unit to select a first slice and second slice in an examination subject, each of said first and second slices containing a portion of a blood vessel and said second slice being located upstream of said first slice in said subject with respect to a flow direction of blood in said blood vessel;
operating said magnetic resonance data acquisition unit to saturate a sodium-23 magnetization in said second slice by radiating a radio-frequency saturation pulse;
after saturating said sodium-23 magnetization in said second slice, operating said magnetic resonance data acquisition unit to execute a magnetic resonance data acquisition sequence to acquire magnetic resonance data, originating from said sodium-23 magnetization, from said first slice;
when selecting said first and second slices, establishing a spatial relationship between said first and second slices that causes the sodium-23 magnetization in the blood vessel to flow from said second slice into said first slice so as to produce a reduced signal proportion in said magnetic resonance data acquired from said first slice; and
providing said magnetic resonance data to a computerized processor and, in said processor, automatically calculating a sodium content in tissue in said first slice from said magnetic resonance data.

2. A method as claimed in claim 1 comprising establishing said spatial relationship between said first slice and said second slice by setting a separation between said first slice and said second slice dependent on at least one of a flow rate of said blood in said blood vessel, and a T1 spin-grid relaxation rate of said sodium-23 magnetization, and a signal strength of magnetic resonance signals produced by said sodium-23 magnetization.

3. A method as claimed in claim 1 comprising establishing said spatial relationship between said first slice and said second slice by setting a thickness of at least one of said first slice or said second slice dependent on at least one of a flow rate of said blood in said blood vessel, and a T1 spin-grid relaxation rate of said sodium-23 magnetization, and a signal strength of magnetic resonance signals produced by said sodium-23 magnetization.

4. A method as claimed in claim 1 comprising establishing said spatial relationship between said first slice and said second slice by setting a separation between said first slice and said second slice and a thickness of at least one of said first slice and said second slice dependent on at least one of a flow rate of said blood in said blood vessel, and a T1 spin-grid relaxation rate of said sodium-23 magnetization, and a signal strength of magnetic resonance signals produced by said sodium-23 magnetization.

5. A method as claimed in claim 1 comprising selecting said first slice and said second slice to each have a same thickness.

6. A method as claimed in claim 1 comprising establishing said spatial relationship between said first slice and said second slice to cause said reduce signal proportion to be less than equal to a predetermined fraction of a total signal of said magnetic resonance data by setting at least one of a thickness of said first slice, a thickness of said second slice, and a separation between said first slice and said second slice.

7. A method as claimed in claim 1 comprising operating said magnetic resonance data acquisition unit to radiate said RF saturation pulse as being slice-selective for said second slice.

8. A method as claimed in claim 1 comprising operating said magnetic resonance data acquisition unit to radiate said RF saturation pulse as a non-slice-selective pulse, and to execute said magnetic resonance data acquisition sequence with a slice-selective additional RF saturation pulse that re-inverts magnetization in said first slice before a remainder of said magnetic resonance data acquisition sequence.

9. A method as claimed in claim 1 comprising selecting said first slice and said second slice to respectively contain portions of the aorta of the subject, as said blood vessel.

10. A magnetic resonance system to measure a sodium content in tissue of a subject, comprising:
a magnetic resonance data acquisition unit;
a sequence controller configured to operate said magnetic resonance data acquisition unit to select a first slice and second slice in an examination subject, each of said first and second slices containing a portion of a blood vessel and said second slice being located upstream of said first slice in said subject with respect to a flow direction of blood in said blood vessel;
said sequence controller being configured to operate said magnetic resonance data acquisition unit to saturate a sodium-23 magnetization in said second slice by radiating a radio-frequency saturation pulse;
after saturating said sodium-23 magnetization in said second slice, said sequence controller being configured to operate said magnetic resonance data acquisition unit to execute a magnetic resonance data acquisition sequence to acquire magnetic resonance data, originating from said sodium-23 magnetization, from said first slice;
said sequence controller, when selecting said first and second slices, being configured to establish a spatial relationship between said first and second slices that causes the sodium-23 magnetization in the blood vessel to flow from said second slice into said first slice so as to produce a reduced signal proportion in said magnetic resonance data acquired from said first slice; and
a computerized processor provided with said magnetic resonance data and configured to automatically calculate a sodium content in tissue in said first slice from said magnetic resonance data.

11. A method to measure a sodium content in tissue, comprising:
determining a blood volume in portions of blood vessels contained in a slice of a subject;
operating a magnetic resonance data acquisition unit to execute a magnetic resonance data acquisition sequence to acquire magnetic resonance data produced by sodium-23 magnetization in said slice;
providing a computerized processor with the determined blood volume and the magnetic resonance data and, in said processor, automatically calculating a signal proportion of said magnetic resonance data that originates from sodium-23 magnetization in said blood vessels, based on the determined blood volume;
in said processor, subtracting said signal proportion from a total signal of said magnetic resonance data to obtain a corrected signal that is proportional to a sodium content in tissue in said slice; and
in said processor, automatically calculating said sodium content in said tissue in said slice from said corrected signal.

12. A method as claimed in claim 11 comprising implementing at least one the determination of the blood volume, the calculation of the signal proportion, and the subtraction, with spatial resolution.

13. A method as claimed in claim 12 comprising operating said magnetic resonance data acquisition unit to acquire said magnetic resonance data with a spatial resolution that is less than an average extent of said portions of blood vessels in said slice.

14. A method as claimed in claim 11 comprising determining said blood volume by operating said magnetic resonance data acquisition unit to execute an additional magnetic resonance data acquisition sequence to acquire additional magnetic resonance data originating from hydrogen-1 magnetization.

15. A method as claimed in claim 14 wherein said slice is a first slice, and comprising executing said additional magnetic resonance data acquisition sequence by radiating an RF saturation pulse in a second slice that is located upstream of said first slice with respect to a flow direction of blood in one of said blood vessels.

16. A method as claimed in claim 11 comprising calculating the signal proportion of the magnetic resonance data that originates from the sodium-23 magnetization in the blood vessels by multiplying a concentration of sodium in said blood with said determined blood volume in said slice.

17. A method as claimed in claim 16 comprising, in said processor, additionally automatically determining a concentration of sodium in said blood.

18. A magnetic resonance system to measure a sodium content in tissue, comprising:
a magnetic resonance data acquisition unit;
a computerized processor configured to determine a blood volume in portions of blood vessels contained in a slice of a subject;
a sequence controller configured to operate said magnetic resonance data acquisition unit to execute a magnetic resonance data acquisition sequence to acquire magnetic resonance data produced by sodium-23 magnetization in said slice;
said processor also being provided with the magnetic resonance data and being configured to automatically calculate a signal proportion of said magnetic resonance data that originates from sodium-23 magnetization in said blood vessels, based on the determined blood volume;
said processor being configured to subtract said signal proportion from a total signal of said magnetic resonance data to obtain a corrected signal that is proportional to a sodium content in tissue in said slice; and
said processor being configured to automatically calculate said sodium content in said tissue in said slice from said corrected signal.
